(19) United States
(12) Patent Application Publication
(10) Pub. No.: US 2022/0012378 A1
(43) Pub. Date: Jan. 13, 2022

(54) METHOD OF PERFORMING DESIGN VERIFICATION WITH AUTOMATIC OPTIMIZATION AND RELATED DESIGN VERIFICATION SYSTEM

(71) Applicant: FEA-OPT TECHNOLOGY CO., LTD., MIAOLI COUNTY (TW)

(72) Inventor: Shen-Yeh Chen, Miaoli County (TW)

(21) Appl. No.: 16/940,350

(22) Filed: Jul. 27, 2020

(30) Foreign Application Priority Data
Jul. 9, 2020 (TW) 109123145

(51) Int. Cl. G06F 30/12; G06F 30/20; G06T 17/20; G06T 17/10

(52) U.S. Cl. CPC G06F 30/12; G06T 17/10; G06T 17/20; G06F 30/20

(57) ABSTRACT

A design verification system includes a CAD system, a CAE system and an optimization determination system. The CAD system is configured to read in a CAD model and a parameter file, update the CAD model based on the parameter file, and convert the updated CAD model into a neutral file for output. The CAE system is configured to read in the neutral file, perform a pre-processing operation and an analysis solving operation on the neutral file, and output a corresponding analysis result. The optimization determination system is configured to determine whether an optimized loop converges based on the analysis result.

### CROSS REFERENCE TO RELATED APPLICATION

This application claims priority of Taiwan Application No. 109123145 filed on 2020 Jul. 9.

### BACKGROUND OF THE INVENTION

### 1. Field of the Invention

The present invention is related to a method of performing design verification with automatic optimization and related design verification system, and more particularly, to a method of performing design verification with automatic optimization by connecting CAD system and CAE system using neutral file and related design verification system.

### 2. Description of the Prior Art

Computer-aided design (CAD) refers to the process of using computer software to aid in the creation, modification, analysis, or optimization of a design. Computer-aided engineering (CAE) refers to the process of using computer software to simulate/verify/optimize a design in order to improve its performance or assist in the resolution of engineering problems for a wide range of industries. CAD and CAE techniques are commonly used in an integrated manner for digital design/verification applications. For example, after creating a product design using CAD, the structural strength, stiffness, flexibility, dynamics, thermal conductivity, coherence, elasticity and mechanics of the CAD design may be analyzed, verified and optimized using CAE.

A typical CAE process includes pre-processing, analysis solving, and post-processing steps. In the pre-processing phase, a CAD model with physical properties of a design is divided and converted into discretized meshes for subsequent analysis. Due to the essential differences between the specialties and key technologies of CAD and CAE, as well as business considerations, software capable of combining CAD and CAE has not been made available yet. For executing the pre-processing operation in an existing CAD/CAE design verification application, CAD models and meshes can be created in the CAE system, or CAE meshes can be created in the CAD system and then outputted to the CAE system. However, the prior art pre-processing operation may cause data distortion due to the essential differences between CAD and CAE techniques. Also, it is difficult for a CAD developer or a CAE developer to specialize both in the product and programming. Therefore, the meshes generated by either party may not have sufficient quality to result in accurate CAE solutions.

Another prior method of executing the pre-processing operation is to establish a bi-directional link between the CAD software and the CAE software. After changing the shape or the parameters of the CAD model, the modified CAD model file may be directly transmitted to the CAE system for verification without resetting the CAE system or re-loading the CAD model. However, the above-mentioned bi-directional link requires function calls to be performed between the CAD software and the CAE software at kernel level, or needs to be written as the plug-ins of the CAD software and the CAE software. In order to allow the CAE software to read in CAD model files and maintain the bi-directional link, the authorization from the CAE software needs to be obtained for accessing the functions or plug-ins in CAD proprietary format. Also, the plug-ins need to be compiled before establishing the bi-directional link, which increases the difficulty and complexity in real applications.

### SUMMARY OF THE INVENTION

The present invention provides a method of performing design verification with automatic optimization. The method includes a CAD system converting an updated CAD model file into a neutral file for output, a CAE system reading in the neutral file, the CAE system performing a pre-processing operation and an analysis solving operation on the neutral file and outputting a corresponding analysis result, and determining whether an optimized loop converges based on the analysis result.

The present invention also provides a design verification system with automatic optimization. The design verification system includes a CAD system configured to convert an updated CAD model file into a neutral file for output; a CAE system configured to read in the neutral file, perform a pre-processing operation and an analysis solving operation on the neutral file, and output a corresponding analysis result; and an optimization determination system configured to determine whether an optimized loop converges based on the analysis result.

These and other objectives of the present invention will no doubt become obvious to those of ordinary skill in the art after reading the following detailed description of the preferred embodiment that is illustrated in the various figures and drawings.

### BRIEF DESCRIPTION OF THE DRAWINGS

FIG. 1 is a functional diagram illustrating a design verification system according to an embodiment of the present invention.

FIG. 2 is a flowchart illustrating a method of performing design verification with automatic optimization according to an embodiment of the present invention.

### DETAILED DESCRIPTION

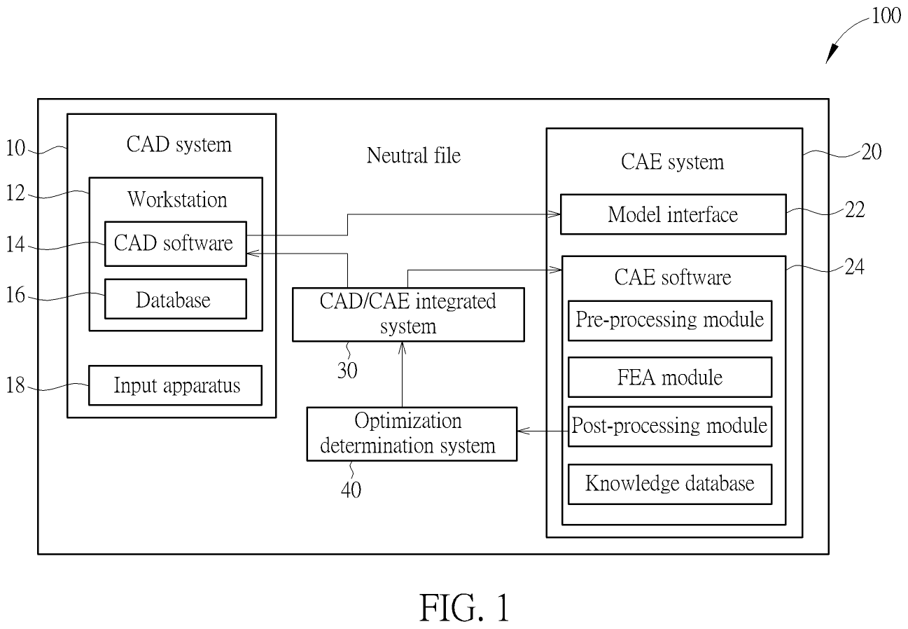

FIG. 1 is a functional diagram illustrating a design verification system 100 according to an embodiment of the present invention. The design verification system 100 includes a CAD system 10, a CAE system 20, a CAD/CAE integrated system 30, and an optimization determination system 40.

In an embodiment of the present invention, the CAD system 10 may be a graphic-orientated automated system capable of providing aid in creation, modification, analysis or optimization of a design. The CAD system 10 includes a workstation 12 and an input apparatus 18. The workstation 12 may be any high-efficiency computer device with graphic-processing and display function, installed with CAD software 14 and storing a database 16. The database 16 includes the feature parameters, precision characteristics or material information of specific products. The CAD software 14 may be general-purpose or specific-purpose software used for, but not limited to, construction, electrical engineering, circuit or other engineering designs. The CAD software 14 provides interactive graphing, analysis of engineering computation and basic attribute processing functions which include, but not limited to, reuse of design components, ease of design modification and versioning, automatic generation of standard components of the design, validation/verification of designs against specifications and design rules, and simulation of designs without building a physical prototype. The input apparatus 18 includes a keyboard, a mouse, a scanner, a digitizer or any device which allows a design draft to be converted into electronic files accessible by the CAD software 14 for modification or editing. However, the implementation of the CAD system 10 does not limit the scope of the present invention.

In an embodiment of the present invention, the CAE system 20 may be a centralized system or a workstation network system configured to receive data provided by the CAD system 10 using a model interface 22 and then execute CAE software 24 for validation/verification. The basic functional structure of the CAE software 24 includes a knowledge database, a pre-processing module, a finite element analysis (FEA) module and a post-processing module. The knowledge database is used for storing expertise in computation analysis which includes theories, algorithms and specifications associated with finite element method, finite volume method, differential equations or other analysis methods. The pre-processing module is configured to perform physical/parameterized modeling, perform Boolean algebra on components, perform automatic unit slicing, perform automatic node numbering, automatically generate node parameters and numbers, directly introduce load and material parameters using parametric equations, automatically apply loads to nodes, and automatically generate model information. The FEA module includes multiple FEA sub-systems configured to divide a model into elements with less complicated geometry than that of the whole initial model based on related algorithms and solutions stored in the knowledge database. The above-mentioned division, commonly known as discretization, helps to investigate the model through its finite elements based on morph conditions. For example, the CAE software 24 may divide a general model with complicated structures into a physics element, a mechanics element and a mathematics element, which may be analyzed separately by a linear static analysis sub-system, a dynamic analysis sub-system, a vibration modal analysis sub-system and a thermal analysis sub-system in the FEA module. The functions of the post-processing module includes data smoothing of the FEA analysis results, balancing and displaying various physical quantities, thorough data check and engineering regulation inspection with respect to product design, design optimization and model modifications. However, the implementation of the CAE system 20 does not limit the scope of the present invention.

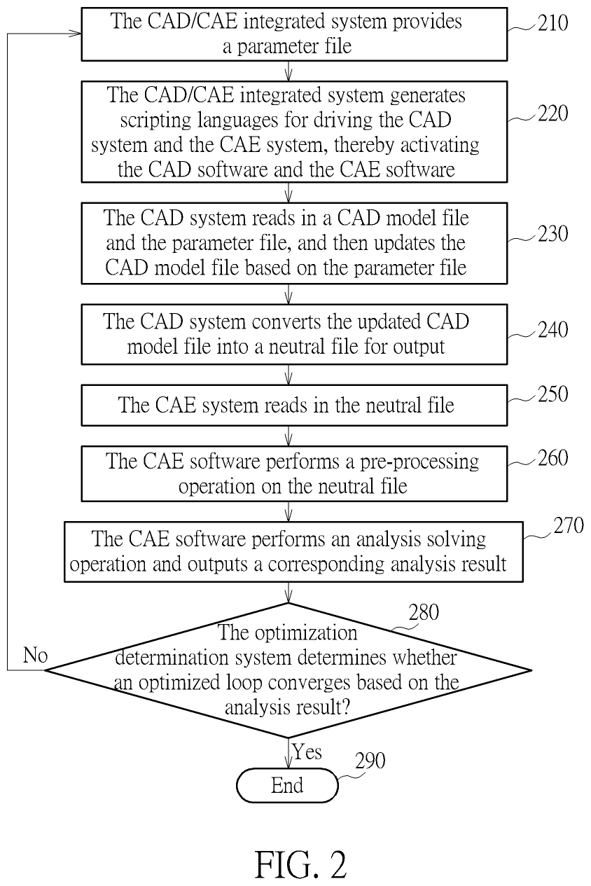

FIG. 2 is a flowchart illustrating a method of performing design verification with automatic optimization according to an embodiment of the present invention. The flowchart in FIG. 2 includes the following steps:

Step 210: the CAD/CAE integrated system 30 provides a parameter file.

Step 220: the CAD/CAE integrated system 30 generates scripting languages for driving the CAD system 10 and the CAE system 20, thereby activating the CAD software 14 and the CAE software 24.

Step 230: the CAD system 10 reads in a CAD model file and the parameter file, and then updates the CAD model file based on the parameter file.

Step 240: the CAD system 10 converts the updated CAD model file into a neutral file for output.

Step 250: the CAE system 20 reads in the neutral file.

Step 260: the CAE software 24 performs a pre-processing operation on the neutral file.

Step 270: the CAE software 24 performs an analysis solving operation and outputs a corresponding analysis result.

Step 280: the optimization determination system 40 determines whether an optimized loop converges based on the analysis result; if yes, execute step 290; if no, execute step 210.

Step 290: end.

In step 210, the CAD/CAE integrated system 30 is configured to provide the parameter file which includes information associated with any change made to CAD model files.

In step 220, the CAD/CAE integrated system 30 is configured to generate the scripting language for driving the CAD system 10 and the scripting language for driving the CAE system 20, respectively. The scripting languages allow the CAD/CAE routine management tasks to be included in a text file which can be interpreted on the user programming interfaces provided by the CAD system 10 and the CAE system with high efficiency, rather than going through an “edit-compile-link-run” process on the application programming interfaces (API) of the CAD system 10 and the CAE system 20.

After being activated by the scripting language generated in step 220 for driving the CAD system 10, the CAD software 14 is configured to read in the parameter file provided by the CAD/CAE integrated system 30 and the CAD model file of a design draft via the input apparatus 18 or from an internal storage device, thereby updating the CAD model file based on the parameter file. Therefore, all repairs or modifications made to a geographical model are performed in the CAD system 10.

In step 240, the CAD system 10 is configured to convert the updated CAD model file into a neutral file for output. In an embodiment, the neutral file may be a STEP file, an STL file, a DXT file or a DWG file which is able to connect the CAD system 10 and the CAE system 20 without via their APIs. However, the type of the neutral file does not limit the scope of the present invention.

After being activated by the scripting language generated in step 220 for driving the CAE system 20, the CAE software 24 is configured to read in the neutral file associated with the updated CAD model file provided by the CAD system 10 in step 250.

In step 260, the pre-processing module of the CAE software 24 is configured to perform the pre-processing operation on the neutral file. During the pre-processing operation, physical conditions are first defined on a predetermined geometric identification. Then, a mesh which conforms to topology labels and geometric elements in the CAE structure may be created.

In step 270, the FEA module of the CAE software 24 is configured to perform the analysis solving operation on the mesh created in step 260 based on the information stored in the knowledge database. Then, the post-processing module of the CAE software 24 may output the corresponding analysis result.

In step 280, the optimization determination system 40 is configured to determine whether the optimized loop converges based on the analysis result. If the optimized loop converges, step 290 is then executed for terminating the method of performing design verification. If the optimized loop does not converge, step 220 is then re-executed for providing the parameter file which includes information associated with further changes made to CAD model files.

In conclusion, in the present design verification system 100, the CAD software and the CAE software are activated using scripting languages, and the CAD system 10 and the CAE system 20 are connected using a neutral file rather than via respective APIs. The present method of executing the pre-processing operation does not require function calls to be performed between the CAD software and the CAE software at kernel level, nor does it need to be written as the plug-ins of the CAD software and the CAE software. Therefore, the present invention can reduce the difficulty and complexity in real CAD/CAE applications for digital design/verification.

Those skilled in the art will readily observe that numerous modifications and alterations of the device and method may be made while retaining the teachings of the invention. Accordingly, the above disclosure should be construed as limited only by the metes and bounds of the appended claims.

What is claimed is:

1. A method of performing design verification with automatic optimization, comprising:
a computer-aided design (CAD) system converting an updated CAD model file into a neutral file for output;
a computer-aided engineering (CAE) system reading in the neutral file;
the CAE system performing a pre-processing operation and an analysis solving operation on the neutral file, and outputting a corresponding analysis result; and
determining whether an optimized loop converges based on the analysis result.

2. The method of claim 1, further comprising:
generating a first scripting language for driving the CAD system and activating a CAD software installed on the CAD system; and
generating a second scripting language for driving the CAE system and activating a CAE software installed on the CAE system.

3. The method of claim 1, further comprising:
providing a parameter file which includes information related to any change made to a CAD model file;
the CAD system reading in the CAD model file and the parameter file; and
the CAD system providing the updated CAD model file by updating the CAD model file according to the parameter file.

4. The method of claim 1, wherein the neutral file is a STEP file, an STL file, a DXT file or a DWG file.

5. The method of claim 1, wherein the CAE system performing the pre-processing operation on the neutral file comprises:
defining physical conditions on a predetermined geometric identification; and
creating a mesh which conforms to topology labels and geometric elements in a CAE structure.

6. A design verification system with automatic optimization, comprising:
a CAD system configured to convert an updated CAD model file into a neutral file for output;
a CAE system configured to:
read in the neutral file;
perform a pre-processing operation and an analysis solving operation on the neutral file, and output a corresponding analysis result; and
an optimization determination system configured to determine whether an optimized loop converges based on the analysis result.

7. The design verification system of claim 6, further comprising a CAD/CAE integrated system configured to:
generate a first scripting language for driving the CAD system and activating a CAD software installed on the CAD system; and
generate a second scripting language for driving the CAE system and activating a CAE software installed on the CAE system.

8. The design verification system of claim 7, wherein:
the CAE system further comprises an input apparatus for reading in a CAD model file; and
the CAD/CAE integrated system is further configured to provide a parameter file which includes information related to any change made to the CAD model file; and
the CAD system is further configured to:
read in the CAD model file and the parameter file; and
provide the updated CAD model file by updating the CAD model file according to the parameter file.

9. The design verification system of claim 6, wherein the neutral file is a STEP file, an STL file, a DXT file or a DWG file.

10. The design verification system of claim 6, wherein the CAE system is further configured to perform the pre-processing operation on the neutral file by:
defining physical conditions on a predetermined geometric identification; and
creating a mesh which conforms to topology labels and geometric elements in a CAE structure.
